(19) United States
(12) Patent Application Publication
(10) Pub. No.: US 2012/0196047 A1
(43) Pub. Date: Aug. 2, 2012

(54) DETERMINING RELATIVE SCAN VELOCITY TO CONTROL ION IMPLANTATION OF WORK PIECE

(75) Inventors: Cheng-Hui Shen, Hsin-Chu (TW); Zhimin Wan, Sunnyvale, CA (US)

(73) Assignee: ADVANCED ION BEAM TECHNOLOGY, INC., Hsin-Chu (TW)

(21) Appl. No.: 13/016,912

(22) Filed: Jan. 28, 2011

(51) Int. Cl. C23C 14/48; G06G 7/62; G06F 17/10; B05C 11/00

(52) U.S. Cl. 427/526; 118/697; 703/2

(57) ABSTRACT

To select a relative velocity profile to be used in scanning an actual work piece with an ion implant beam of an ion implantation tool, the implantation of a virtual work piece is simulated. A dose distribution is calculated across the virtual work piece based on an implant beam profile and a relative velocity profile. A new relative velocity profile is then determined based on the calculated dose distribution and the relative velocity profile used in calculating the dose distribution. A new dose distribution is then calculated using the new relative velocity profile. A new relative velocity profile is determined and a corresponding new dose distribution is calculated iteratively until the new dose distribution meets one or more predetermined criteria. The new relative velocity profile is stored as the selected relative velocity profile when the new dose distribution meets the one or more predetermined criteria.

### BACKGROUND

1. Field

This application relates generally to ion implantation of a work piece, and more specifically to controlling the dose distribution across a work piece by simulating the implantation dose distribution across the work piece and modifying the relative scan velocity profile used in simulation and subsequent implantation.

2. Related Art

Dopant implantation is used to introduce conductivity-altering impurities, such as ions, into a work piece, such as a silicon wafer, a semiconductor plate, or a glass plate. The impurity material to be implanted may be ionized in an ion source and then separated in a mass analyzer to form an ion implant beam with ions of a specific charge-to-mass ratio. The ion implant beam may then be accelerated or otherwise modified before being directed to the work piece. The charged ions strike the surface and then penetrate into the work piece so that a desired conductive region is formed. Because the work piece surface area is usually significantly larger than the cross-sectional area of the ion implant beam, the work piece, the ion implant beam, or both are moved relative to one another, sometimes in a raster-scan method, so that the whole surface of a work piece may be implanted by the ion implant beam. As a result, a dose distribution of potentially varying dose concentration is formed across the surface of the work piece. Dose concentration may be measured in atoms/cm² (atoms per centimeter squared). The dose distribution is generally a function of the implant beam profile (or implant beam current distribution), the manner in which the work piece is scanned relative to the ion implant beam, and the velocity with which the work piece is scanned relative to the ion implant beam.

For mass production, it is preferable to have a uniform dose distribution of nearly constant implantation dose concentration across the work piece. Because the dose distribution is a function of the implant beam profile, the manner in which the work piece is scanned relative to the ion implant beam, and the velocity with which the work piece is scanned relative to the ion implant beam, must be carefully controlled and adjusted to ensure that the requisite dose distribution is generated on each work piece.

One approach to ensuring uniform dose distribution is to carefully tune the ion implant beam before scanning the work piece with the ion implant beam. The ion implant beam is usually tuned to obtain a predetermined implant beam shape and implant beam current distribution along the cross-section of the beam in order to enhance throughput of properly implanted work pieces with the required dose distribution as well as to simplify the scanning step. For example, a Gaussian-like implant beam shape and current distribution may be preferred, so the ion implant beam would be tuned until the shape and the current distribution of the beam meet predetermined thresholds of the Gaussian-like shape and distribution. Tuning, however, is limited by the practical capabilities of the implant beam source, the mass analyzer, the accelerator, and the other components of an ion implantation tool. It is sometimes, therefore, difficult to tune the ion implant beam to obtain the desired shape and current distribution, and time spent tuning the beam can be costly both in wasted implantation time and wasted ion implantation tool operating expenses.

In some instances, the ion implant beam is tuned to an elongated oval shape or ribbon where the longer cross-sectional dimension is at least as long as the diameter of the work piece, so that the whole work piece may be implanted in a single scan of the beam. This approach, however, results in wasting the portion of the ion implant beam that does not get implanted as it lands outside the dimensions of the circular work piece. In response, the implant beam current density is decreased to avoid significant ion losses, and the time period required for implantation increases as a result.

In other instances, the work piece is rotated during scanning to reduce the amount of ion implant beam tuning required before scanning. The ion implant beam in these instances may not be tuned at all or may only be partially tuned before scanning. The work piece is then continuously rotated at a constant or varying velocity, or the work piece may be rotated step-by-step by discrete amounts such that the work piece is rotated and scanned with the beam multiple times, halting rotation before each scan after each discrete rotation. For example, the ion implant beam may be tuned until it has a smooth shape and current distribution, but not necessarily a Gaussian-like shape and distribution. The work piece may then be rotated continuously during scanning or rotated step-by-step during multiple scans in order to implant ions more uniformly across the work piece. It has been unclear, however, how to efficiently determine an optimal relative scan velocity profile defining the velocity with which the work piece should be scanned relative to the ion implant beam to obtain a desired dose distribution.

### SUMMARY

In one exemplary embodiment, the implantation of a virtual work piece, which simulates or characterizes an actual work piece to be implanted by the ion implant beam, is simulated to select a relative velocity profile to be used in scanning the actual work piece with the ion implant beam of an ion implantation tool. A dose distribution across the virtual work piece is calculated based on an implant beam profile of an ion implantation tool and an initial relative velocity profile between the ion implant beam and the virtual work piece. A new relative velocity profile between the ion implant beam and the virtual work piece is then determined based on the calculated dose distribution and the relative velocity profile used in calculating the dose distribution. A new dose distribution across the virtual work piece is then calculated based on the implant beam profile and the new relative velocity profile. This new dose distribution is then analyzed to determine whether or not it meets one or more predetermined criteria such as dose uniformity or minimum dose concentration. If the new calculated dose distribution does not meet the criteria, a new relative velocity profile is determined based on the last calculated dose distribution and relative velocity profile, and a new dose distribution is then calculated based on this new relative velocity profile. The process of determining a new relative velocity profile and calculating a corresponding new dose distribution continues iteratively using the results of each prior calculation to determine a new relative velocity profile. The process terminates when a new relative velocity profile is obtained that yields a dose distribution across the virtual work piece that meets the one or more predetermined criteria. This new relative velocity profile is then stored as the selected relative velocity profile. In one embodiment, this new relative velocity profile may then be used to implant an actual work piece by scanning the actual work piece one or more times with the ion implant beam of an ion implantation tool using the new relative velocity profile to control the velocity with which the work piece is scanned with the ion implant beam.

### BRIEF DESCRIPTION OF THE FIGURES

The present application can be best understood by reference to the following description taken in conjunction with the accompanying figures, in which like parts may be referred to by like numerals.

FIG. 1 illustrates an exemplary process for determining a selected relative velocity profile.

FIG. 2 illustrates an exemplary graph of dose distribution across a work piece.

FIG. 3 illustrates an exemplary graph of dose distribution across a work piece based on one iteration of determining a new relative velocity profile via simulation.

FIG. 4 illustrates an exemplary graph of dose distribution across a work piece based on two iterations of determining a new relative velocity profile via simulation.

FIG. 5 illustrates an exemplary graph of dose distribution across a work piece based on three iterations of determining a new relative velocity profile via simulation.

FIG. 6 illustrates an exemplary graph of dose distribution across a work piece based on four iterations of determining a new relative velocity profile via simulation.

FIG. 7 illustrates an exemplary graph of dose distribution across a work piece based on five iterations of determining a new relative velocity profile via simulation.

FIG. 8 illustrates an exemplary graph of dose distribution across a work piece based on six iterations of determining a new relative velocity profile via simulation.

FIG. 9 illustrates an exemplary graph of dose distribution across a work piece based on seven iterations of determining a new relative velocity profile via simulation.

FIG. 10 illustrates an exemplary graph of dose distribution across a work piece based on eight iterations of determining a new relative velocity profile via simulation.

FIG. 11 illustrates an exemplary graph of an original relative velocity profile and eight succeeding relative velocity profiles determined iteratively via simulation.

FIG. 12 illustrates an exemplary ion implantation tool.

FIG. 13 illustrates an exemplary scanning system.

### DETAILED DESCRIPTION

The following description is presented to enable a person of ordinary skill in the art to make and use the various embodiments. Descriptions of specific devices, techniques, and applications are provided only as examples. Various modifications to the examples described herein will be readily apparent to those of ordinary skill in the art, and the general principles defined herein may be applied to other examples and applications without departing from the spirit and scope of the various embodiments. Thus, the various embodiments are not intended to be limited to the examples described herein and shown, but are to be accorded the scope consistent with the claims.

### Overview of Process for Determining Velocity Profile

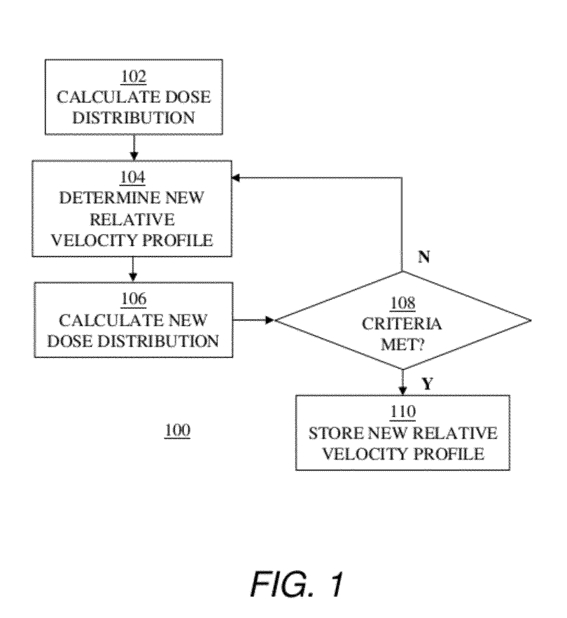

To illustrate the process described in detail below, FIG. 1 is provided depicting an exemplary process 100 for determining a selected relative velocity profile to be used in scanning a work piece with an ion implant beam. As an overview, the following brief description of exemplary process 100 is provided in conjunction with FIG. 1.

In step 102, a dose distribution across a virtual work piece, which simulates or characterizes an actual work piece to be implanted by the ion implant beam, is calculated in simulation using an implant beam profile and an initial relative velocity profile. The implant beam profile may or may not be measured from the ion implant beam of an ion implantation tool, and factors like tilting angle, rotation profile, rotation velocity profile, or other factors may or may not be used in calculating the dose distribution in step 102.

In step 104, a new relative velocity profile between the ion implant beam and the virtual work piece is determined based on at least the calculated dose distribution from step 102 and the relative velocity profile used in calculating the dose distribution. In step 106, a new dose distribution is calculated as in step 102, but using the new relative velocity profile determined in step 104 and the implant beam profile to calculate the new dose distribution.

The new dose distribution calculated in step 106 is then analyzed in step 108 to determine whether or not the new dose distribution meets one or more predetermined criteria such as dose uniformity or other criteria related to a desired dose distribution. Steps 104 and 106 are repeated until the new dose distribution meets the one or more predetermined criteria. In one exemplary embodiment, in repeating steps 104 and 106, the new relative velocity profile in step 104 is determined using the most recently calculated dose distribution in step 106 and the corresponding new relative velocity profile from the previous iteration through step 104.

When the new calculated dose distribution from step 106 meets the one or more predetermined criteria, the new relative velocity profile determined in the most recent iteration through step 104 is stored in step 110. The new relative velocity profile stored in step 110 is the relative velocity profile that, when used as the relative velocity profile in implanting an actual work piece, would yield a dose distribution across the actual work piece that meets the one or more predetermined criteria, as verified in step 108 on the virtual work piece in the simulation. The relative velocity profile stored in step 110 may, therefore, be used to implant an actual work piece by scanning the work piece with the ion implant beam using the stored relative velocity profile to dictate the velocity with which the work piece is scanned with the ion implant beam.

### Detailed Process for Determining Velocity Profile

As described briefly above, FIG. 1 illustrates an exemplary process 100 for determining a selected relative velocity profile to be used in scanning a work piece with an ion implant beam. The following detailed description of exemplary process 100 is provided in conjunction with FIG. 1 to further illustrate the exemplary process.

In step 102, a dose distribution across a virtual work piece is calculated in simulation using an implant beam profile and an initial relative velocity profile. The implant beam profile may or may not be measured from the ion implant beam of an ion implantation tool, and factors like tilting angle, rotation profile, rotation velocity profile, or other factors may or may not be used in calculating the dose distribution in step 102.

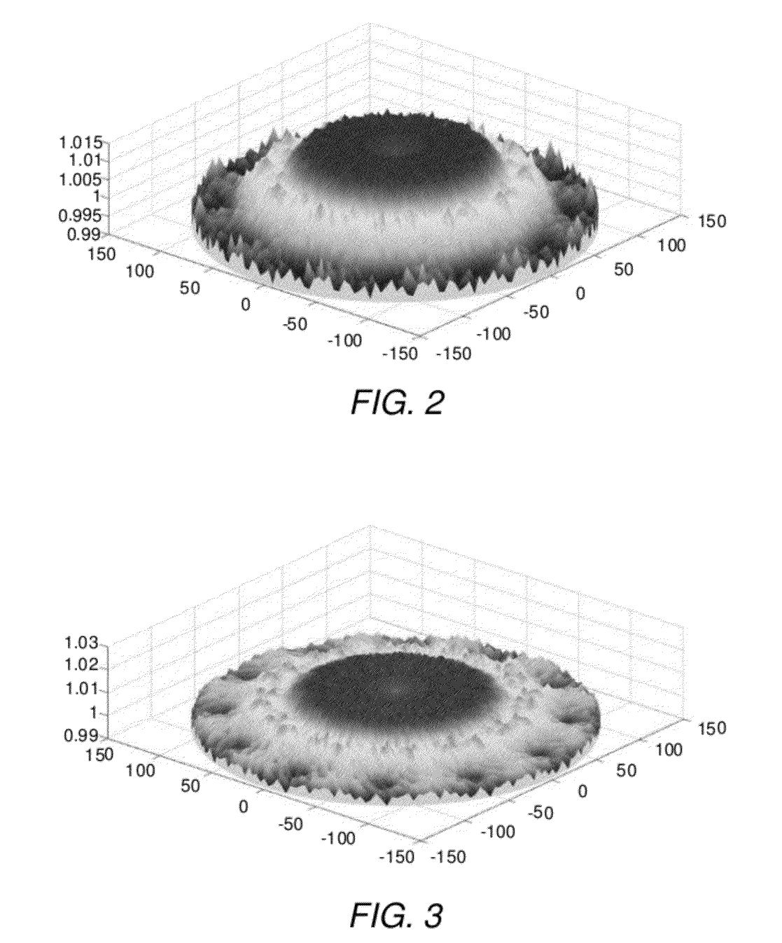

FIG. 2 illustrates an exemplary graph of dose distribution across a work piece. As depicted, an exemplary work piece may be circular and measure 300 mm in diameter across the surface of the work piece. An exemplary work piece may measure 775 μm in thickness. One of ordinary skill in the art would recognize that there exists a wide variety of different work pieces that may be implanted with dopant material. For instance, work pieces to be implanted with dopant material may include silicon wafers, semiconductor plates, or glass plates. Moreover, work pieces may vary in size and shape, although thin circular disks or wafers are common, which may measure less than 100 mm, 100 mm, 200 mm, 300 mm, 450 mm, or more in diameter. Work pieces may also vary in thickness such as less than 275 μm, 275 μm, 375 μm, 525 μm, 625 μm, 675 μm, 725 μm, 775 μm, 925 μm, or more. To implant dopant material onto a work piece, an ion implant beam of charged ions or other dopant material is scanned across the work piece. Due to the limitations of the implant beam source, mass analyzer, accelerator, and other implanter components, the dose distribution across the work piece can vary widely, as depicted in FIG. 2. FIG. 2 illustrates a three-dimensional view of dose concentration showing that, in some instances, common methods of dopant implantation can result in areas of high dopant concentration, represented by the darkest and thickest shading in the graph of FIG. 2, and other areas of comparably much lower concentration, represented by the thinnest shading in the graph of FIG. 2.

Dopant dose distribution, an example of which is depicted graphically in FIG. 2, is generally a function of the implant beam profile (or implant beam current distribution), the manner in which the work piece is scanned relative to the ion implant beam, and the velocity with which the work piece is scanned relative to the ion implant beam. In one exemplary embodiment, the ion implant beam of an ion implantation tool is measured to determine the implant beam profile. The implant beam profile may include one or more characteristics of the ion implant beam such as cross-sectional beam width, cross-sectional beam height, beam intensity, beam power, beam shape, beam current, or other beam characteristics known to those skilled in the art that may affect the resulting dopant implantation.

In one embodiment, a simulation is performed before implanting a work piece with dopant material in order to control the resulting dose distribution in the work piece. In the simulation, a dose distribution across a virtual work piece is calculated (step 102 of FIG. 1) based on at least an implant beam profile and a relative velocity profile between the ion implant beam and the virtual work piece. The dose distribution across the virtual work piece may be calculated using a formula such as

$$D ( {x}_{i} , {y}_{i} ) = \frac{B ( {x}_{i} 1 , {y}_{i} 1 )}{V ( {x}_{i} 1 , {y}_{i} 1 )} + \frac{B ( {x}_{i} 2 , {y}_{i} 2 )}{V ( {x}_{i} 2 , {y}_{i} 2 )} + \frac{B ( {x}_{i} 3 , {y}_{i} 3 )}{V ( {x}_{i} 3 , {y}_{i} 3 )} + … + \frac{B ( {x}_{i} ( n - 1 ) , {y}_{i} ( n - 1 ) )}{V ( {x}_{i} ( n - 1 ) , {y}_{i} ( n - 1 ) )} + \frac{B ( {x}_{i} n , {y}_{i} n )}{V ( {x}_{i} n , {y}_{i} n )} , \qquad ( 1 )$$

where D(xᵢ, yᵢ) is the dose concentration on the work piece at coordinate (x, y), B(xᵢn, yᵢn) is the implant beam current, V(xᵢn, yᵢn) is the relative velocity profile, n is the scan number, and i is the wafer data point number. The implant beam profile may have been measured from an ion implantation tool as described above. The relative velocity profile is the velocity with which the virtual work piece is to be scanned with the ion implant beam. The relative velocity profile may be a constant velocity, a time-varying velocity, a position-varying velocity, or other velocity profile indicating how the work piece is to be scanned relative to the ion implant beam. For the initial dose distribution calculation, the relative velocity profile used in the calculation may be a predetermined relative velocity profile such as a common relative velocity profile with which work pieces are scanned. Alternatively, the relative velocity profile to be used in the initial calculation may be a predetermined constant velocity profile or any other initial velocity profile useful for simulating how a work piece will be implanted.

The results of an exemplary initial dose distribution calculation are graphically depicted in FIG. 2. It should be appreciated, however, that the simulation need not be depicted visually in order to control the dose distribution, and the results of the initial dose distribution calculation may be stored in any useful manner, which would be readily apparent to those of ordinary skill in the art. In one embodiment, the initial dose distribution may then be analyzed to determine whether or not it meets one or more predetermined criteria. For instance, the initial dose distribution across the virtual work piece may be compared to a desired dose distribution to determine whether or not the implant beam profile and the relative velocity profile, when used for implanting an actual work piece, would yield a satisfactory dose distribution. Many different criteria may be analyzed in determining whether or not the dose distribution is satisfactory. For instance, the uniformity of the initial dose distribution may be calculated to determine how much variation exists in the dose concentration across the work piece. A desired uniformity may already have been determined based on the requirements of a particular work piece, and the calculated uniformity of the initial dose distribution may then be compared to this desired uniformity to determine whether or not it meets the criterion. The desired uniformity, in one embodiment, may be an allowed range of dose concentration across the work piece, or it may be a work piece uniformity calculated as a percentage of deviation from some desired dose concentration.

Other criteria that may be used in determining whether or not the initial dose distribution is satisfactory include a predetermined dose concentration or range of dose concentration at one or more points across the work piece, a minimum dose concentration at one or more points across the work piece, a maximum dose concentration at one or more points across the work piece, or any other criteria that one skilled in the art would recognize may be useful in ensuring a desired dose distribution across a work piece for a particular application. In some instances, the desired dose distribution may be a varied dose concentration at different points across the work piece, and one skilled in the art would know how to determine appropriate criteria, and how to analyze the initial dose distribution to determine whether or not it meets the predetermined criteria. It should be appreciated that a single criterion may be used to determine whether or not the initial dose distribution is satisfactory, or a combination of two, three, four, five, six, seven, eight, nine, or more criteria may be used to determine whether or not the initial dose distribution is satisfactory for a particular application.

In one embodiment, if the initial calculated dose distribution on the virtual work piece is deemed satisfactory for a particular application, the relative velocity profile used in the initial calculation may then be stored as the selected relative velocity profile to be used in implanting an actual work piece, and the simulation may be terminated. The stored relative velocity profile may then be used to implant an actual work piece: the work piece is scanned with the ion implant beam at the velocity dictated by the stored relative velocity profile.

With reference again to FIG. 1, if the initial calculated dose distribution is analyzed and deemed unsatisfactory, a new relative velocity profile between the ion implant beam and the virtual work piece is determined in step 104 based on the initial calculated dose distribution and the relative velocity profile used in calculating the initial dose distribution. In another embodiment, the initial calculated dose distribution may not be analyzed, but the initial calculated dose distribution may still be used in step 104 to determine a new relative velocity profile between the ion implant beam and the virtual work piece. This new relative velocity profile is determined in order to improve the dose distribution across the virtual work piece to meet or come closer to meeting the one or more predetermined criteria. The new relative velocity profile may be determined in a variety of ways. For instance, the new relative velocity profile may be determined based on the formula:

V(x)=Vi(x)*(2−Ji(x)/Jo), (2)

where V(x) is the new relative velocity profile, Ji(x) is the initial calculated dose distribution, Vi(x) is the relative velocity profile used to calculate the initial dose distribution Ji(x), and Jo is the desired constant dose concentration, and where x is a position on the work piece and (2*Jo)>Ji(x)>0 for any x. The new relative velocity profile may also be determined based on the formula:

V(x)=Vi(x)*Jo/Ji(x), (3)

where V(x) is the new relative velocity profile, Ji(x) is the initial calculated dose distribution, Vi(x) is the relative velocity profile used to calculate the initial dose distribution Ji(x), and Jo is the desired constant dose concentration, and where x is a position on the work piece and (2*Jo)>Ji(x)>0 for any x. Although equations (2) and (3) are intended to calculate a new relative velocity profile to obtain a dose distribution of a constant desired dose concentration Jo, they are given for example only, and it should be appreciated that the new relative velocity profile may be calculated to obtain a dose concentration that varies with position on the work piece or to obtain any other desired dose distribution.

With reference again to FIG. 1, after a new relative velocity profile is determined in step 104, a new dose distribution is calculated in step 106 based on the implant beam profile and the new relative velocity profile using the same process described above in calculating the initial dose distribution. The results of an exemplary dose distribution calculation after determining a new relative velocity profile are graphically illustrated in FIG. 3. It should be appreciated that the dose distribution depicted in FIG. 3 (based on a newly determined relative velocity profile) is more uniform than the dose distribution depicted in FIG. 2 (before the relative velocity profile was modified). It should be noted that, although the vertical scale of FIG. 3 is larger than the vertical scale of FIG. 2, there is a noticeable improvement in dose uniformity from FIG. 2 to FIG. 3 (the scale on FIG. 2 is exaggerated to emphasize problematic variation in dose concentration that may be minimized by determining and using a new relative velocity profile following the process herein).

With reference again to FIG. 1, after a new dose distribution is calculated in step 106 based on the new relative velocity profile, the new dose distribution may be analyzed in step 108 to determine whether or not it meets one or more predetermined criteria, as discussed above. The new calculated dose distribution across the virtual work piece may be compared to a desired dose distribution to determine whether or not the implant beam profile and the new relative velocity profile, when used for implanting an actual work piece, would yield a satisfactory dose distribution. As discussed above, in making this determination, many different criteria may be analyzed including dose uniformity, range of dose concentration, percentage of deviation from desired dose concentration, a predetermined dose concentration or range of dose concentration at one or more points across the work piece, a minimum dose concentration at one or more points across the work piece, a maximum dose concentration at one or more points across the work piece, or any other criteria that one skilled in the art would recognize may be useful in ensuring a desired dose distribution across a work piece for a particular application. In some instances, the desired dose distribution may be a varied dose concentration at different points across the work piece, and one skilled in the art would know how to determine appropriate criteria, and how to analyze the new calculated dose distribution to determine whether or not it meets the predetermined criteria. It should be appreciated that a single criterion may be used to determine whether or not the new calculated dose distribution is satisfactory, or a combination of two, three, four, five, six, seven, eight, nine, or more criteria may be used to determine whether or not the new calculated dose distribution is satisfactory for a particular application.

With reference again to FIG. 1, if the new calculated dose distribution on the virtual work piece is deemed satisfactory for a particular application in step 108, the new relative velocity profile used in the most recent dose distribution calculation may then be stored in step 110 as the selected relative velocity profile to be used in implanting an actual work piece, and the simulation may be terminated. The stored relative velocity profile may then be used to implant an actual work piece: the work piece is scanned with the ion implant beam at the velocity dictated by the stored relative velocity profile.

If the new calculated dose distribution on the virtual work piece does not meet the one or more predetermined criteria and is deemed unsatisfactory in step 108, an iterative process may be used to determine a new relative velocity profile to obtain a desired dose distribution on the virtual work piece. Each new relative velocity profile between the ion implant beam and the virtual work piece is determined based on a previously calculated and analyzed dose distribution and a relative velocity profile used in calculating a previous dose distribution. Each new relative velocity profile is determined in step 104 as described above to further improve the dose distribution across the virtual work piece to meet or come closer to meeting the one or more predetermined criteria. Each new relative velocity profile may be determined in a variety of ways. For instance, a new relative velocity profile may be determined based on one of the following formulas:

Vm(x)=Vn(x)*(2−Jn(x)/Jo), (4)

Vm(x)=Vn(x)*Jo/Jn(x), (5)

where, in either formula, Vm(x) is the new relative velocity profile being determined, Jn(x) is the most recently calculated dose distribution, Vn(x) is the relative velocity profile used to calculate the dose distribution Jn(x), and Jo is the desired constant dose concentration; and where x is a position on the work piece, (2*Jo)>Jn(x)>0 for any x, m and n represent iteration numbers, and m>n, and n=(m−1), indicating that the current iteration is calculated using data from the most recent iteration.

A new relative velocity profile may also be determined based on one of the following formulas:

Vm(x)=Vi(x)*(2−Jn(x)/Jo), (6)

Vm(x)=Vi(x)*Jo/Jn(x), (7)

where, in either formula, Vm(x) is the new relative velocity profile being determined, Jn(x) is a dose distribution calculated in an earlier iteration, Vi(x) is the relative velocity profile used to calculate the initial dose distribution, and Jo is the desired constant dose concentration; and where x is a position on the work piece, (2*Jo)>Jn(x)>0 for any x, m and n represent iteration numbers, and m>n indicating that the current iteration is calculated using data from earlier iterations.

A new relative velocity profile may also be determined based on one of the following formulas:

Vm(x)=Vn(x)*(2−Ji(x)/Jo), (8)

Vm(x)=Vn(x)*Jo/Ji(x), (9)

where, in either formula, Vm(x) is the new relative velocity profile being determined, Ji(x) is the initial calculated dose distribution, Vn(x) is a relative velocity profile used in an earlier iteration, and Jo is the desired constant dose concentration; and where x is a position on the work piece, (2*Jo)>Jn(x)>0 for any x, m and n represent iteration numbers, and m>n indicating that the current iteration is calculated using data from earlier iterations.

A new relative velocity profile may also be determined based on one of the following formulas:

Vm(x)=Vn(x)*(2−Jp(x)/Jo), (10)

Vm(x)=Vn(x)*Jo/Jp(x), (11)

where, in either formula, Vm(x) is the new relative velocity profile being determined, Jp(x) is a dose distribution calculated in an earlier iteration, Vn(x) is a relative velocity profile used in an earlier iteration, and Jo is the desired constant dose concentration; and where x is a position on the work piece; (2*Jo)>Jn(x)>0 for any x; m, n, and p represent iteration numbers; m>n; and m>p indicating that the current iteration is calculated using data from earlier iterations.

Any of equations (1)-(11) may be used exclusively or in combination with one or more other formulas in order to determine a new relative velocity profile. Although equations (1)-(11) are intended to calculate a new relative velocity profile to obtain a dose distribution of a constant desired dose concentration Jo, they are given for example only, and it should be appreciated that the new relative velocity profile may be calculated to obtain a dose concentration that varies with position on the work piece or to obtain any other desired dose distribution.

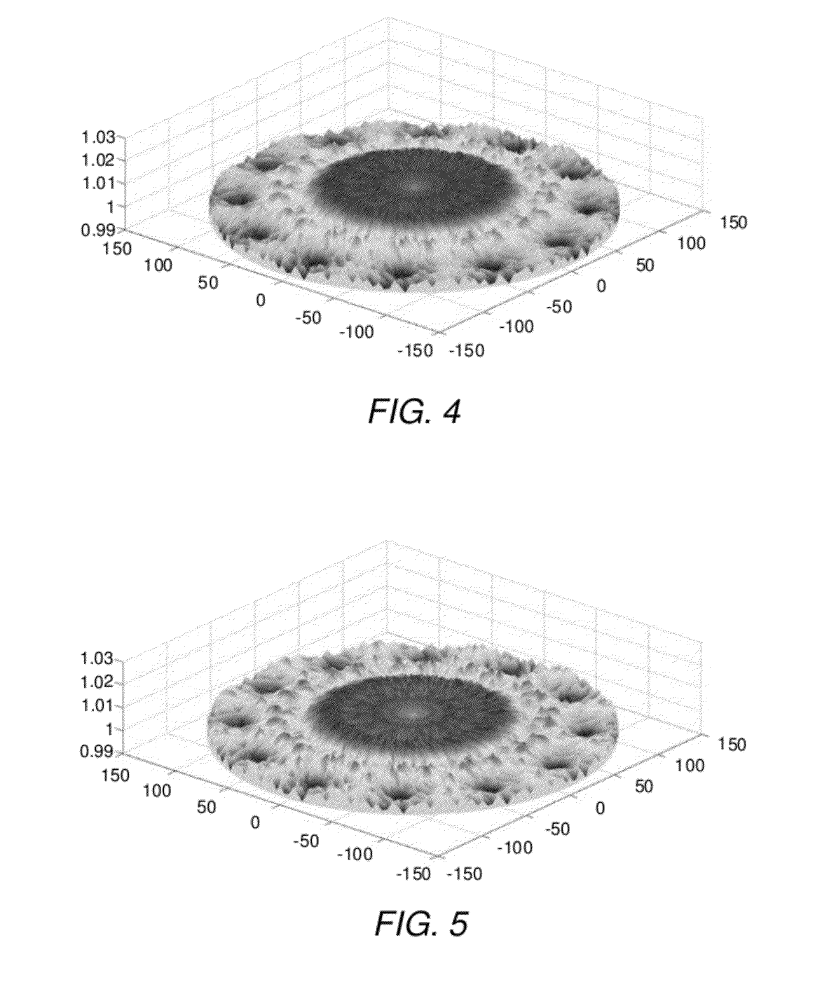

During the iterative process, after each new relative velocity profile is determined in step 104, a new dose distribution is calculated in step 106 based on the implant beam profile and the new relative velocity profile using the same process described above in calculating the initial dose distribution. The results of an exemplary dose distribution calculation after a second iteration of determining a new relative velocity profile are graphically illustrated in FIG. 4. FIG. 4 shows an exemplary dose distribution calculated using a relative velocity profile that was determined using data from an earlier iteration (the earlier iteration results are graphically illustrated in FIG. 3). It should be appreciated that the dose distribution depicted in FIG. 4 (second iteration) is more uniform than the dose distribution depicted in FIG. 3 (first iteration), showing the resulting improvement from iteratively determining a new relative velocity profile.

After a new dose distribution is calculated in step 106 based on the new relative velocity profile from step 104, the new dose distribution may be analyzed in step 108 to determine whether or not it meets one or more predetermined criteria, as discussed above. In one embodiment, if the new calculated dose distribution on the virtual work piece is deemed satisfactory for a particular application, the new relative velocity profile used in the most recent dose distribution calculation may then be stored in step 110 as the selected relative velocity profile to be used in implanting an actual work piece, and the iterative process and simulation may be terminated. The stored relative velocity profile may then be used to implant an actual work piece: the work piece is scanned with the ion implant beam at the velocity dictated by the stored relative velocity profile.

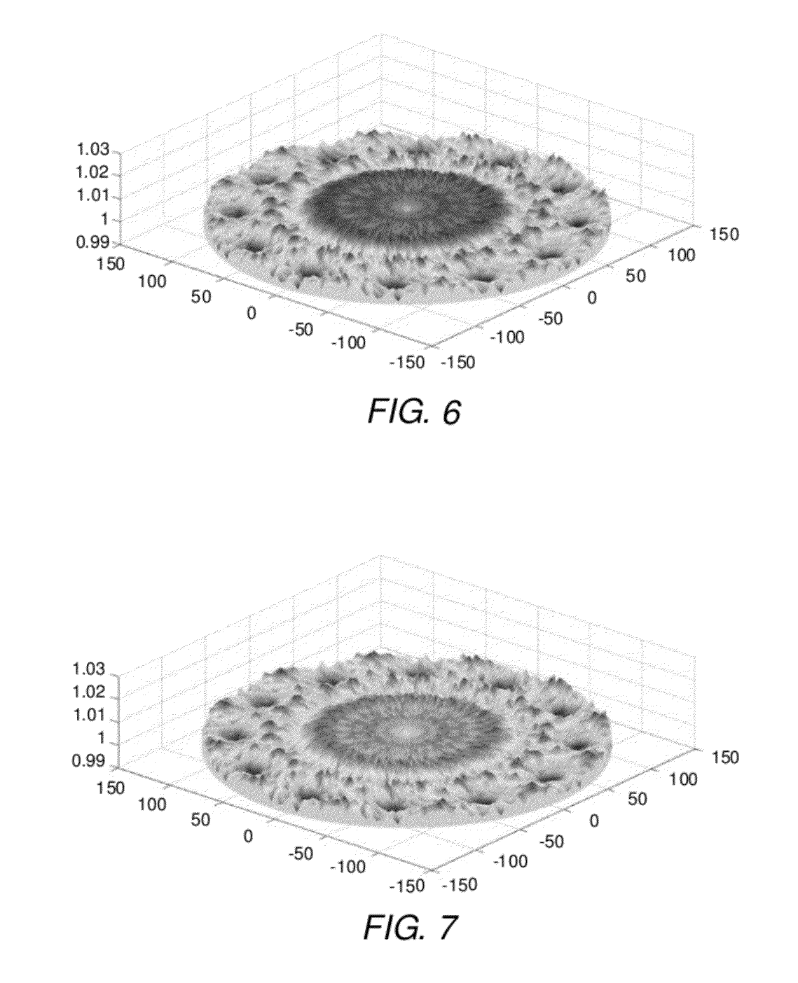

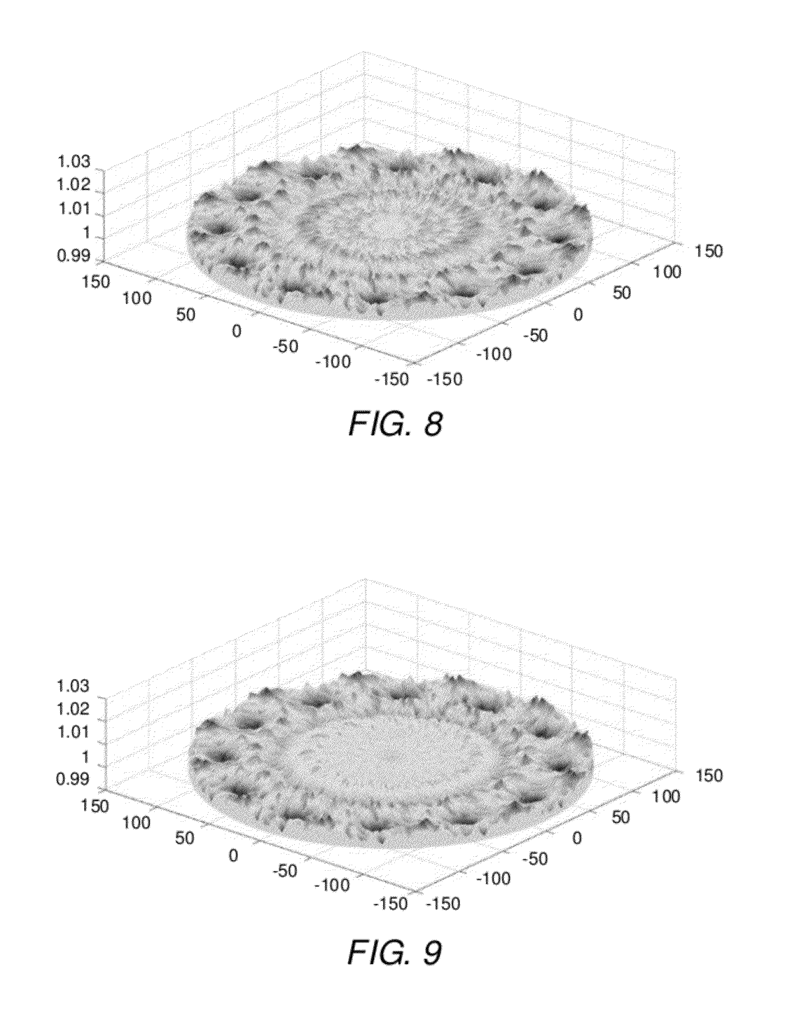

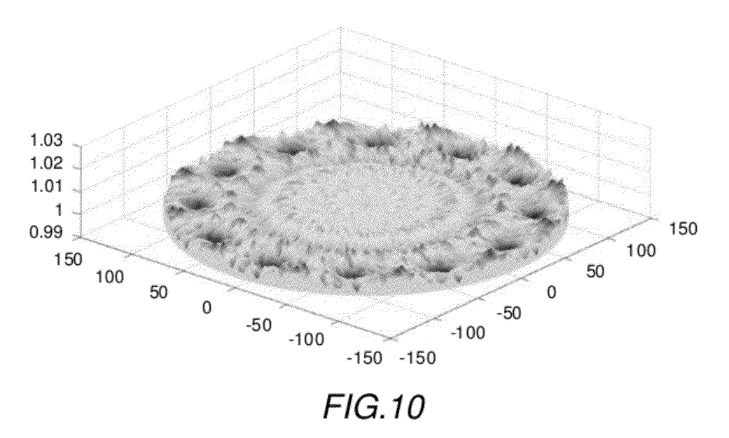

If the new calculated dose distribution on the virtual work piece does not meet the one or more predetermined criteria and is deemed unsatisfactory in step 108, the iterative process may continue to obtain a desired dose distribution on the virtual work piece. The steps of determining a new relative velocity profile in step 104, calculating a new dose distribution in step 106, and analyzing the new dose distribution in step 108 may be repeated multiple times as necessary. For instance, in one embodiment, a single iteration may be performed to determine one new relative velocity profile and the corresponding new dose distribution. In another embodiment, two, three, four, five, six, seven, eight, nine, ten, or more iterations may be performed, determining a new relative velocity profile and a new corresponding dose distribution in each iteration. FIGS. 3-10 graphically illustrate the results of successive iterations of determining a new relative velocity profile and a corresponding dose distribution. It should be appreciated that the dose uniformity depicted across the virtual work piece improves with each successive iteration in the example. FIG. 10 illustrates the results of an exemplary eighth and final iteration where the dose distribution does meet the one or more predetermined criteria, halting the iterative process and the simulation, and allowing the new relative velocity profile to be stored as the selected relative velocity profile. The stored relative velocity profile may then be used to implant an actual work piece: the work piece is scanned with the ion implant beam at the velocity dictated by the stored relative velocity profile.

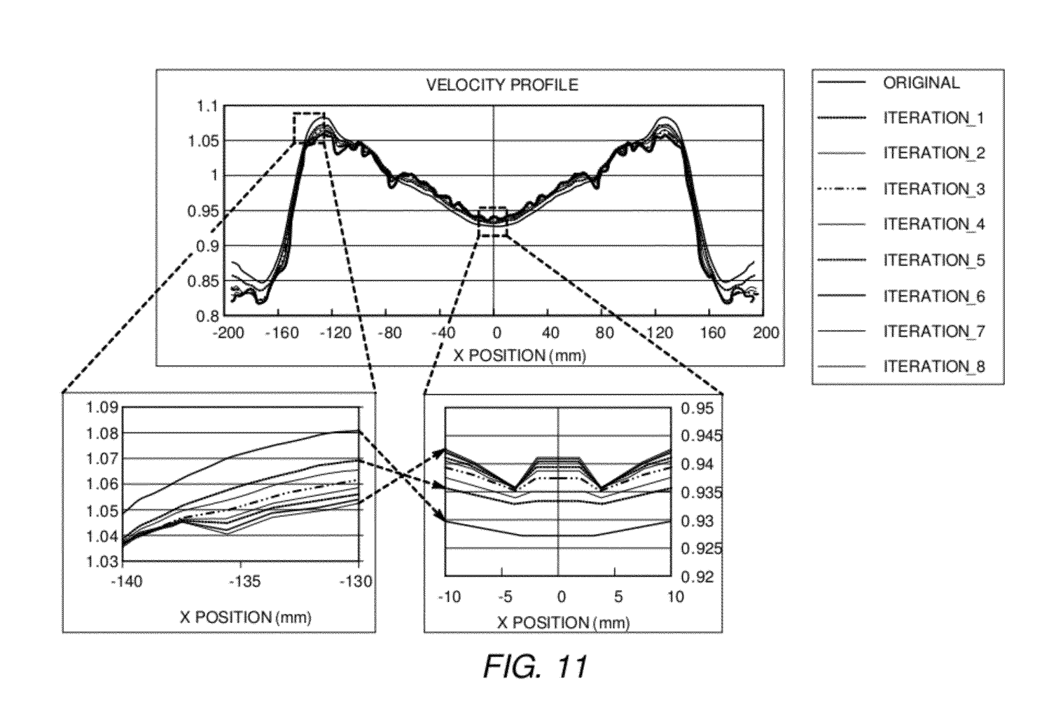

FIG. 11 illustrates an exemplary graph of an original relative velocity profile and eight succeeding relative velocity profiles determined iteratively via simulation. Two zoomed in portions are shown below the graph to depict the detail of the exemplary profiles and the difference between each iteration. As shown, a velocity profile may indicate the relative velocity with which an exemplary 300 mm work piece may be scanned. The velocity profile may extend beyond the boundaries of the work piece to capture the acceleration and deceleration of the work piece relative to the beam, as shown by the regions left of −150 mm and right of 150 mm on the x axis.

The above-described simulation and iterative process are further illustrated by comparing the exemplary velocity profiles depicted in FIG. 11 and the corresponding exemplary dose distributions depicted in FIGS. 2-10. For instance, the initial dose distribution of FIG. 2 was calculated with the “ORIGINAL” velocity profile depicted in FIG. 11. Each subsequent exemplary dose distribution corresponds to each subsequent velocity profile iteration through the eighth and final dose distribution in FIG. 10, which corresponds to the “ITERATION_{—}8” velocity profile depicted in FIG. 11. As shown in FIG. 2, the dose concentration at the center of the work piece was initially higher than the dose concentration elsewhere on the work piece. After eight iterations of determining a new relative velocity profile following the process described above, the dose concentration across the virtual work piece became more uniform as shown in FIG. 10. Looking in particular at the zoomed in portion of the velocity profile graph around the 0 mm position, it should be recognized that the eighth and final velocity profile has a higher relative velocity near the center of the work piece than the original velocity profile. Referring to the center of the virtual work piece, this higher velocity profile thus resulted in decreased dose concentration compared to the initial dose distribution. Increasing the relative velocity of the work piece decreases the amount of dopant material that is deposited at a location on the work piece, and conversely, decreasing the relative velocity of the work piece increases the amount of dopant material that is deposited at a location on the work piece. Therefore, through the exemplary simulation and iterative process described above, an improved relative velocity profile may be determined that, when used to implant an actual work piece, may yield a more uniform dose distribution. It should be recognized that FIGS. 2-11 are exemplary and that dose distributions and velocity profiles can vary from those depicted in FIGS. 2-11.

Although reference has been made to calculating the dose distribution across a virtual work piece, it should be recognized that simplifications and approximations may be used during the above-described simulation while still obtaining a desired dose distribution by adjusting the relative velocity profile. For instance, 16 mode scanning may be used to approximate continuous rotation scanning: the dose distribution across the virtual work piece may be calculated assuming the work piece is to be scanned 16 times with the ion implant beam, the work piece being rotated a discrete amount between each scan, although the actual work piece may then be implanted using continuous rotation scanning. Some approximations may simplify the calculation, reduce processing time, or both while yielding sufficiently accurate results. In one embodiment, quad mode scanning may be sufficiently accurate to approximate continuous rotation: the work piece is simulated as being scanned four times with the ion implant beam, although the actual work piece may then be implanted using continuous rotation scanning. It should be noted that FIGS. 2-10 graphically illustrate dose distribution calculated using 16 mode scanning. The resulting velocity profile in the example, however, may be used in implanting an actual work piece using 16 mode scanning, continuous rotation scanning, or some combination so long as the approximation is sufficiently accurate for the particular application. One skilled in the art will recognize other simplifications and approximations that may be used in performing the simulation on a virtual work piece that may simplify calculations, reduce processing time, simplify implementation, or otherwise improve the simulation process without losing the accuracy needed to obtain a desired dose distribution across an actual work piece.

It should be appreciated that the process described above for implanting a work piece may be modified in a variety of ways, and one skilled in the art would be able to select and implement appropriate modifications for a particular application. For instance, due to the crystalline structure of work pieces like silicon wafers, it is often desirable or necessary to tilt the work piece relative to the ion implant beam for scanning so the depth of penetration of dopant material may be better controlled. A work piece may, therefore, be tilted such that the ion implant beam strikes the surface of the work piece at a non-perpendicular angle, and the tilting angle may be adjusted to improve the dose distribution on a work piece. In one embodiment, as part of the simulation described above, the tilting angle may be adjusted in order to improve the dose distribution across the virtual work piece. In another embodiment, a tilting profile may be used as part of the simulation described above, where the tilting profile is two or more different tilting angles at which the work piece is to be scanned, either changing tilting angle during a scan or changing tilting angle in between consecutive scans. In the simulation, while determining a new relative velocity profile, the tilting profile may also be modified. A modified tilting profile may then be used in the subsequent calculation of the dose distribution. In this embodiment, when the dose distribution meets the one or more criteria, the tilting profile used in the most recent calculation may be stored and used to scan an actual work piece.

In another embodiment, the rotation velocity profile may be modified to obtain an improved dose distribution. For work pieces that are to be rotated continuously during scanning, the rotation velocity profile is the velocity with which the work piece is to be rotated during scanning in a plane perpendicular or nearly perpendicular to the ion implant beam. The rotation plane depends on how the work piece is to be tilted, which may vary relative to the ion implant beam. For example, the rotation plane may be nearly perpendicular to the ion implant beam at angles smaller than 30°, 30°, 35°, 40°, 45°, 50°, 55°, 60°, 65°, 70°, 75°, 80°, 85°, or any other angle relative to the ion implant beam, or it may be perpendicular to the ion implant beam. In one embodiment, the rotation velocity profile may be a constant velocity such that the work piece is rotated continuously at a constant rate during scanning. In another embodiment, the rotation velocity profile may be a varying non-zero velocity such that the work piece is rotated continuously, without stopping, but at a rate that may vary with time, position, or both during scanning. In one embodiment, as part of the simulation described above, the rotation velocity profile may be adjusted in order to improve the dose distribution across the virtual work piece. In the simulation, while determining a new relative velocity profile, the rotation velocity profile may also be modified. The modified rotation velocity profile may then be used in the subsequent calculation of the dose distribution. In this embodiment, when the dose distribution meets the one or more criteria, the rotation velocity profile used in the most recent calculation may be stored and used to scan an actual work piece.

In another embodiment, the rotation profile may be adjusted when a work piece is to be scanned two or more times with the ion implant beam. In some embodiments, a work piece may be scanned multiple times without rotating the work piece while dopant material is being implanted on the work piece. In between consecutive scans, however, the work piece may be rotated by a discrete amount. For example, the work piece may be scanned without rotating the work piece, the scan may be stopped, the work piece may be rotated by a discrete amount, and then the work piece may be scanned again without rotating the work piece while dopant material is implanted on the work piece. The work piece may be scanned multiple times; for instance, 2, 3, 4, 5, 6, 7, 8, 9, 10, 11, 12, 13, 14, 15, 16, 17, 18, 19, 20, or more times, with or without a rotation in between each consecutive scan. The amount of rotation between each consecutive scan may vary. The rotation profile is the discrete amount or amounts by which the work piece is to be rotated in between each consecutive scan. In one embodiment, as part of the simulation described above, the rotation profile may be adjusted in order to improve the dose distribution across the virtual work piece. In the simulation, while determining a new relative velocity profile, the rotation profile may also be modified. A modified rotation profile may then be used in the subsequent calculation of the dose distribution. In this embodiment, when the dose distribution meets the one or more criteria, the rotation profile used in the most recent calculation may be stored and used to scan an actual work piece.

In another embodiment, the simulation and iterative process described above may be halted or paused for a variety of reasons. For instance, if one or more predetermined thresholds are exceeded, the iterations may be halted or paused, the data from the most recent calculation may or may not be stored, and an actual work piece may or may not be implanted with dopant material. Setting a threshold may help avoid excessive lag times in simulation, optimize operational performance, avoid exceeding mechanical limitations such as maximum or minimum velocities, or help enforce any other limitation one skilled in the art would recognize as ensuring better performance in the implantation process. For example, in one embodiment, a threshold may be set to limit the maximum number of dose distribution calculations. When the threshold is met or exceeded, the iterative process and simulation may then be terminated, and the threshold condition may be reported to a system operator or may trigger other operations such as taking a new measurement of the implant beam profile, tuning the ion implant beam, or modifying any of a variety of implantation settings such as the rotation profile, rotation velocity profile, and tilting profile discussed above.

A variety of potential predetermined thresholds exist that will be readily apparent to one skilled in the art. For instance, predetermined thresholds may comprise one or more of maximum scan velocity, minimum scan velocity, maximum dose concentration, minimum dose concentration, maximum number of dose distribution calculations, maximum time allotted for calculating dose distributions, maximum variation in relative velocity profile, minimum improvement of the dose distribution between subsequent iterations, or other thresholds readily apparent to one of skill in the art that may halt iterations or simulation. Moreover, some useful predetermined thresholds may vary depending on the ion implantation tool used in a particular application, and one skilled in the art would be able to select appropriate thresholds for a particular implementation.

In one embodiment, if one or more predetermined thresholds are exceeded, the simulation and iterative process may be paused or halted, and the ion implant beam may then be further tuned to obtain a more desirable implant beam profile. The new implant beam profile may then be measured, and a new simulation may be started to optimize the dose distribution using the new implant beam profile. Alternatively, after tuning the ion implant beam, the simulation may continue where it had been paused earlier. In one embodiment, when a threshold is exceeded, data from the simulation relating to possible causes of one or more threshold conditions may be used to tune the ion implant beam to particularly avoid a threshold condition in a subsequent iteration. In another embodiment, when one or more predetermined thresholds are exceeded, the thresholds may be reported to a system operator or stored, and the simulation and iterative process may continue and an actual work piece may be implanted despite the threshold condition being met. In yet another embodiment, when a threshold is exceeded, data from the simulation may be used to modify any other ion implantation tool setting, and an actual work piece may then be implanted or the simulation may continue with the updated ion implantation tool setting. These threshold examples should not be seen as limiting, and one skilled in the art would recognize other thresholds and responses that improve the implantation process in particular applications.

In another embodiment, if a new implant beam profile of the ion implant beam of the ion implantation tool is made available at any point during or in between different steps of the simulation, the new implant beam profile may be obtained, and the simulation may be started again using the new implant beam profile. A new implant beam profile may, for example, become available if the ion implant beam changes shape over time or if the ion implant beam is still being adjusted when the simulation is started. Alternatively, the ion implant beam may have a warm-up or start-up period in which the ion implant beam is subject to change, and the simulation process may be paused and started again with a new implant beam profile at any time should one become available.

In one embodiment, when an implant beam profile is measured on the ion implantation tool and the above-described simulation is being performed, the ion implant beam is maintained during the simulation to avoid altering the implant beam profile. Also, the new relative velocity profile may then be used upon completion of the simulation to implant an actual work piece using the unchanged implant beam profile. The ion implant beam can be tuned before the implant beam profile is measured. Alternatively, the ion implant beam can be partially tuned prior to measuring the implant beam profile. In one embodiment, the ion implant beam can be tuned for a specified amount of time or until certain implant beam profile thresholds are met, the implant beam profile can then be measured and the data used to simulate implantation on a virtual work piece to obtain a desired dose distribution with a selected relative velocity profile. An actual work piece can then be implanted with the tuned ion implant beam using the selected relative velocity profile.

With regard to references herein of implanting an actual work piece with an ion implant beam, it should be recognized that the ion implant beam may be kept stationary while the work piece is moved, the ion implant beam may be moved while the work piece is kept stationary, or a combination of moving the work piece and moving the ion implant beam may be used to scan the work piece. These variations may also be used in simulating implantation of a virtual work piece.

### Ion Implantation Tool

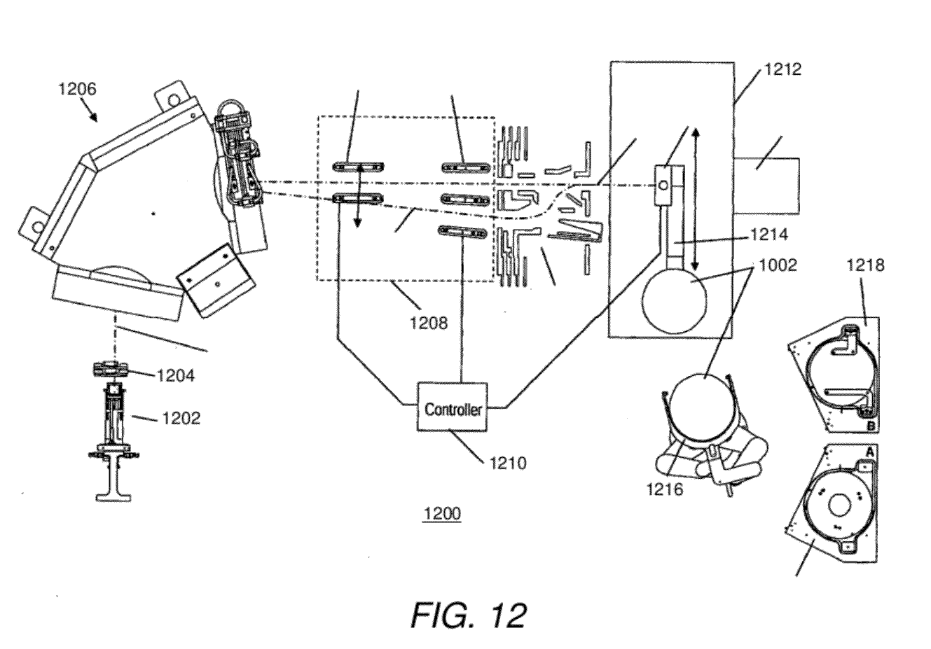

FIG. 12 illustrates an exemplary ion implantation tool 1200 to implant dopant material on one or more work pieces, such as wafers 1002, using the exemplary processes described above. Ion implantation tool 1200 includes a source 1202, extraction optics 1204, analyzer magnets 1206, focusing system 1208, controller 1210, and target chamber 1212. An individual wafer 1002 is held, positioned, and translated in target chamber 1212 using arm 1214. Wafers 1002 are transported between target chamber 1212 and one or more load ports 1218 using robot arm 1216. Controller 1210 can be configured to perform the processes described above. For a more detailed description of implantation tool 1200, see U.S. Pat. No. 7,326,941, which is incorporated herein by reference in its entirety for all purposes.

### Scanning System

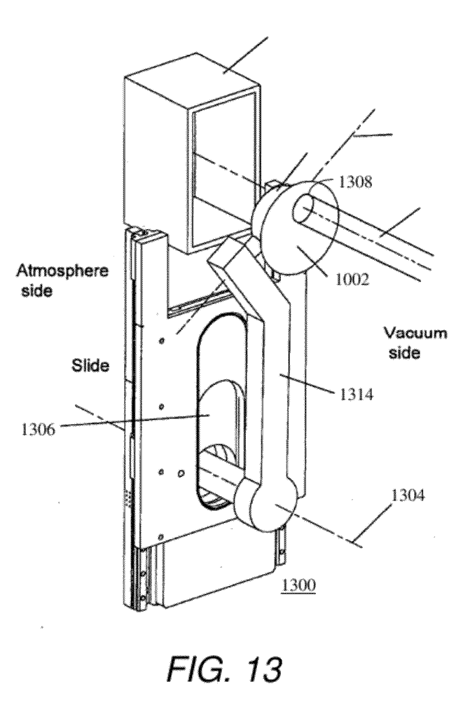

FIG. 13 illustrates an exemplary scanning system 1300 used in ion implantation tool 1200 (FIG. 12). Scanning system 1300 includes arm 1314 that rotates about axis 1304. Arm 1314 also moves along slide 1306. Thus, the combined rotation and translation of arm 1314 allow for ion implant beam 1308 to scan wafer 1002. For a more detailed description of a scanning system, see U.S. Pat. No. 7,057,192, which is incorporated herein by reference in its entirety for all purposes.

### System Variations

It should be recognized that the ion implant beam 1308 can be moved instead of or in addition to moving wafer 1002. Wafer 1002 may also be rotated about an axis other than axis 1304. In addition, wafer 1002 is referenced only as an example and could be any other work piece upon which a dopant material is to be implanted. Although an exemplary ion implantation tool 1200 and exemplary scanning system 1300 have been illustrated and described above, it should be recognized that the processes described above can be implemented using various types of ion implantation tools and scanning systems.

Although only certain exemplary embodiments have been described in detail above, those skilled in the art will readily appreciate that many modifications are possible in the exemplary embodiments without materially departing from the novel teachings and advantages provided herein. Accordingly, the general principles defined herein may be applied to other examples and applications without departing from the spirit and scope of the various embodiments.

We claim:

1. A method for ion implanting of an actual work piece using an ion implant beam of an ion implantation tool, the method comprising:
simulating the ion implantation of a virtual work piece to determine a selected relative velocity profile to be used in scanning the actual work piece with the ion implant beam of the ion implantation tool, wherein simulating comprises:
a) calculating a dose distribution across the virtual work piece based on at least an implant beam profile and a relative velocity profile between the ion implant beam and the virtual work piece;
b) determining a new relative velocity profile between the ion implant beam and the virtual work piece based on at least the calculated dose distribution and the relative velocity profile used in calculating the dose distribution;
c) calculating a new dose distribution across the virtual work piece based on at least the implant beam profile and the new relative velocity profile determined in step b);
d) if the new calculated dose distribution from step c) does not meet one or more predetermined criteria, repeating steps b) and c); and
e) storing the new relative velocity profile determined in step b) as the selected relative velocity profile when the calculated dose distribution across the virtual work piece meets the one or more predetermined criteria; and
implanting the actual work piece by scanning the actual work piece one or more times with the ion implant beam of the implantation tool using the new relative velocity profile stored in e).

2. The method of claim 1, further comprising:
before steps a)-c), measuring the ion implant beam of the implantation tool to obtain the implant beam profile to be used in steps a)-c), wherein the implant beam profile comprises one or more of beam width, beam height, beam intensity, beam power, beam shape, or beam current.

3. The method of claim 2, wherein the ion implant beam profile of the ion implantation tool is maintained without further tuning or adjustment during simulation and implantation while the new relative velocity profile is determined and while the actual work piece is scanned.

4. The method of claim 1, wherein implanting the actual work piece comprises tilting the actual work piece at a non-perpendicular angle relative to the ion implant beam.

5. The method of claim 4, wherein a tilting profile is used in calculating the dose distribution in steps a) and c), and wherein the tilting profile is two or more different tilting angles at which the actual work piece is to be tilted.

6. The method of claim 1, wherein implanting the actual work piece comprises rotating the actual work piece continuously in a plane approximately perpendicular to the ion implant beam, wherein a rotation velocity profile is used in calculating the dose distribution in steps a) and c), and wherein the rotation velocity profile is the rate at which the actual work piece is to be rotated.

7. The method of claim 6, wherein the actual work piece is to be rotated continuously at a constant velocity, and wherein the rotation velocity profile is the constant velocity.

8. The method of claim 6, wherein the actual work piece is to be rotated continuously at a varying non-zero velocity, and wherein the rotation velocity profile is the varying non-zero velocity.

9. The method of claim 6, wherein a new rotation velocity profile is determined in step b) based on at least the calculated dose distribution and the rotation velocity profile used in calculating the dose distribution, wherein the new rotation velocity profile is used in calculating the dose distribution in step c), and wherein the new rotation velocity profile is stored in step e).

10. The method of claim 9, wherein, during implanting, the actual work piece is scanned one or more times with the ion implant beam of the ion implantation tool using the new relative velocity profile and the new rotation velocity profile stored in step e).

11. The method of claim 1, wherein implanting comprises scanning the actual work piece with the ion implant beam two or more times.

12. The method of claim 11, wherein implanting comprises rotating the actual work piece by one or more discrete amounts, wherein rotation of the actual work piece is halted after the actual work piece is rotated by the one or more discrete amounts prior to each scan by the ion implant beam, wherein a rotation profile is used in calculating the dose distribution in steps a) and c), and wherein the rotation profile is the one or more discrete amounts by which the actual work piece is to be rotated.

13. The method of claim 12, wherein a new rotation profile is determined in step b) based on at least the calculated dose distribution and the rotation profile used in calculating the dose distribution, wherein the new rotation profile is used in calculating the dose distribution in step c), and wherein the new rotation profile is stored in step e).

14. The method of claim 13, wherein, during implanting, the actual work piece is scanned one or more times with the ion implant beam of the ion implantation tool using the new relative velocity profile and the new rotation profile stored in step e).

15. The method of claim 1, wherein, during implanting, the ion implant beam is kept stationary while the actual work piece is moved to scan the actual work piece with the ion implant beam.

16. The method of claim 1, wherein, during implanting, the ion implant beam is moved while the actual work piece is kept stationary to scan the actual work piece with the ion implant beam.

17. The method of claim 1, wherein the one or more predetermined criteria comprises one or more of uniformity of the dose distribution across the virtual work piece, a predetermined dose concentration at one or more points across the virtual work piece, a minimum dose concentration at one or more points across the virtual work piece, or a maximum dose concentration at one or more points across the virtual work piece.

18. The method of claim 1, further comprising:
after step c) but before step d), if one or more predetermined thresholds are exceeded, skipping step d), wherein the one or more predetermined thresholds comprises one or more of maximum scan velocity, minimum scan velocity, maximum dose concentration, minimum dose concentration, maximum number of dose distribution calculations, maximum time allotted for calculating dose distributions, maximum variation in relative velocity profile, or minimum improvement of the dose distribution between subsequent iterations.

19. The method of claim 18, further comprising:
when one or more predetermined thresholds are exceeded, adjusting the ion implant beam, obtaining a new implant beam profile, and starting step a) with the new implant beam profile.

20. The method of claim 1, further comprising:
in performing steps a)-e), when a new implant beam profile of the ion implant beam of the ion implantation tool is available, obtaining the new implant beam profile, and starting step a) with the new implant beam profile.

21. The method of claim 1, further comprising:
after step a) but before step b), if the calculated dose distribution from step a) meets one or more predetermined criteria, skipping steps b)-e) and storing the relative velocity profile used in step a) as the selected relative velocity profile.

22. The method of claim 1, wherein the new calculated dose distribution from step c) is used in repeating step b), and wherein a new relative velocity profile is determined and a new dose distribution is calculated in repeating steps b) and c).

23. A method for determining by simulation a selected relative velocity profile to be used in scanning an actual work piece with an ion implant beam of an ion implantation tool, the method comprising:
a) calculating a dose distribution across a virtual work piece based on at least an implant beam profile and a relative velocity profile between the ion implant beam and the virtual work piece;
b) determining a new relative velocity profile between the ion implant beam and the virtual work piece based on at least the calculated dose distribution and the relative velocity profile used in calculating the dose distribution;
c) calculating a new dose distribution across the virtual work piece based on at least the implant beam profile and the new relative velocity profile determined in step b);
d) if the new calculated dose distribution from step c) does not meet one or more predetermined criteria, repeating steps b) and c); and
e) storing the new relative velocity profile determined in step b) as the selected relative velocity profile when the calculated dose distribution across the virtual work piece meets the one or more predetermined criteria.

24. The method of claim 23, wherein the new calculated dose distribution from step c) is used in repeating step b), and wherein a new relative velocity profile is determined and a new dose distribution is calculated in repeating steps b) and c).

25. A computer-readable storage medium containing computer-executable instructions for determining by simulation a selected relative velocity profile to be used in scanning an actual work piece with an ion implant beam of an ion implantation tool, comprising instructions for:
a) calculating a dose distribution across a virtual work piece based on at least an implant beam profile and a relative velocity profile between the ion implant beam and the virtual work piece;
b) determining a new relative velocity profile between the ion implant beam and the virtual work piece based on at least the calculated dose distribution and the relative velocity profile used in calculating the dose distribution;
c) calculating a new dose distribution across the virtual work piece based on at least the implant beam profile and the new relative velocity profile determined in step b);
d) if the new calculated dose distribution from step c) does not meet one or more predetermined criteria, repeating steps b) and c); and
e) storing the new relative velocity profile determined in step b) as the selected relative velocity profile when the calculated dose distribution across the virtual work piece meets the one or more predetermined criteria.

26. The computer-readable storage medium of claim 25, wherein the new calculated dose distribution from step c) is used in repeating step b), and wherein a new relative velocity profile is determined and a new dose distribution is calculated in repeating steps b) and c).

27. An ion implantation tool for implanting dopant material on an actual work piece, comprising:
a source of an ion implant beam;
a focusing system configured to focus the ion implant beam;
a target chamber configured to position the actual work piece; and
a controller configured to scan the ion implant beam across the actual work piece in the target chamber using a selected relative velocity profile,
wherein the selected relative velocity profile was determined by a simulation, wherein the simulation comprises:
a) calculating a dose distribution across a virtual work piece based on at least an implant beam profile and a relative velocity profile between the ion implant beam and the virtual work piece;
b) determining a new relative velocity profile between the ion implant beam and the virtual work piece based on at least the calculated dose distribution and the relative velocity profile used in calculating the dose distribution;
c) calculating a new dose distribution across the virtual work piece based on at least the implant beam profile and the new relative velocity profile determined in step b);
d) if the new calculated dose distribution from step c) does not meet one or more predetermined criteria, repeating steps b) and c); and
e) storing the new relative velocity profile determined in step b) as the selected relative velocity profile when the calculated dose distribution across the virtual work piece meets the one or more predetermined criteria.
